(19) United States
(12) Patent Application Publication
(10) Pub. No.: US 2003/0075210 A1
(43) Pub. Date: Apr. 24, 2003

(54) Photovoltaic modules with a thermoplastic hot-melt adhesive layer and a process for their production

(76) Inventors: Gunther Stollwerck, Krefeld (DE); Christian Hassler, Krefeld (DE); Eckard Foltin, Sinzig (DE); Gerhard Opelka, Leverkusen (DE); Bernd Post, Moers (DE); Jurgen Hattig, Dormagen (DE)

Correspondence Address: BAYER CORPORATION, 100 BAYER ROAD, PITTSBURGH, PA, 15205, US

(21) Appl. No.: 10/266,212

(22) Filed: Oct. 8, 2002

(30) Foreign Application Priority Data
Oct. 12, 2001 (DE) 10150515.9

(51) Int. Cl. H02N 6/00; H01L 25/00; H01L 31/00

(52) U.S. Cl. 136/243; 136/252

(57) ABSTRACT

The invention relates to photovoltaic modules with a specific thermoplastic adhesive layer and the production thereof.

### FIELD OF THE INVENTION

The invention relates to photovoltaic modules with a specific thermoplastic adhesive layer and their production.

### BACKGROUND OF THE INVENTION

Photovoltaic modules or solar modules are understood as meaning photovoltaic structural elements for direct generation of electric current from light, in particular sunlight. Key factors for a cost-efficient generation of solar currents are the efficiency of the solar cells used and the production costs and life of the solar modules.

A solar module conventionally contains a composite of glass, a circuit of solar cells, an embedding material and a reverse side construction. The individual layers of the solar module have to fulfill the following functions:

The front glass (top layer) is used for protection from mechanical and weathering influences. It must have a very high transparency in order to keep absorption losses in the optical spectral range from 350 nm to 1,150 nm and therefore, losses in efficiency of the silicon solar cells conventionally employed for generating current as low as possible. Hardened, low-iron flint glass (3 or 4 mm thick), the degree of transmission of which in the abovementioned spectral range is 90 to 92%, is usually used.

The embedding material (EVA (ethylene/vinyl acetate) films are usually used) is used for gluing the module composite. EVA melts during the laminating operation at about 150° C. and as a result, also flows into the intermediate spaces of the solar cells which are soldered or are connected to each other by means of conductive adhesives, during which process the EVA undergoes thermal crosslinking. The formation of air bubbles, which lead to losses by reflection, is avoided by lamination in vacuum and under mechanical pressure.

The reverse side of the module protects the solar cells and the embedding material from moisture and oxygen. It is also used as mechanical protection from scratching etc. during assembling of the solar modules and as electrical insulation. The reverse side construction can also either be made of glass, but frequently a composite film is used. The variants PVF (polyvinyl fluoride)-PET (polyethylene terephthalate)-PVF or PVF-aluminum-PVF are substantially employed in the composite film.

The so-called encapsulating materials employed in the solar module construction (for the module front side and reverse side) must have, in particular, good barrier properties against water vapor and oxygen. The solar cells, themselves, are not attacked by water vapor or oxygen, but corrosion of the metal contacts and a chemical degradation of the EVA embedding material occurs. A destroyed solar cell contact leads to a complete failure of the module, since all the solar cells in a module are usually electrically connected in series. Degradation of the EVA manifests itself in a yellowing of the module, together with a corresponding reduction in output due to absorption of light and a visual deterioration. About 80% of all modules are currently encapsulated with one of the composite films described on the reverse side, and in about 15% of solar modules glass is used for the front and reverse side. In the latter case, casting resins which are highly transparent but cure only slowly (over several hours) are in some cases employed instead of EVA as the embedding material.

In order to achieve current production costs of solar current which are competitive in spite of the relatively high investment costs, solar modules must achieve long operating times. The solar modules of today are, therefore, designed for a life of 20 to 30 years. In addition to a high stability to weathering, high demands are made on the temperature stability of the modules, the temperature of which during operation can vary in cycles of between +80° C. in full sunlight and temperatures below freezing point (at night). Solar modules are accordingly subjected to extensive stability tests (standard tests according to IEC 61215), which include weathering tests (UV irradiation, damp heat, temperature change), and also hail impact tests and tests in respect of the electrical insulating capacity.

With 30% of the total costs, a relatively high proportion of the production costs for photovoltaic modules falls to the module construction. This high proportion of the module production is due to high material costs (hail-proof front glass 3 to 4 mm thick, composite film on the reverse side) and to long process times, i.e. low productivity. The individual layers of the module composite which are described above are still assembled and aligned manually. In addition, the melting and the relatively slow crosslinking of the EVA hot-melt adhesive and the lamination of the module composite at approx. 150° C. and in vacuum leads to cycle times of about 20 to 30 minutes per module.

Because of the relatively thick front glass pane (3 to 4 mm), conventional solar modules, furthermore, are heavy, which in turn necessitates stable and expensive holding constructions. The removal of heat in the case of the solar modules of today also is solved only unsatisfactorily. In full sunlight, the modules heat up to 80° C., which leads to a temperature-related deterioration in the efficiency of the solar cells and therefore, in the end, an increase in the cost of the solar current.

Various set-ups to reduce the module production costs by less expensive production processes have not so far been accepted. The patent application WO 94/22 172 describes the use of a roller laminator instead of the vacuum plate laminator (vacuum hot press) employed hitherto, the films of plastic used being suitable to only a limited extent for encapsulating solar modules. The films mentioned are neither impact-resistant enough nor sufficiently stable to weathering, nor is the adhesive layer flexible enough in order to provide effective mechanical protection for the highly fragile solar cells.

The Patent Applications JP-A 09-312410 and JP-A 09-312408 describe the use of thermoplastic polyurethanes or elastomers as the adhesive layer for the solar modules. The solar modules are designed for solar cars. The solar cells must be protected from mechanical vibrations. This is realized by extremely soft TPUs, which are significantly softer than EVA. Gluing is effected with the aid of vacuum, which, as already described above, requires long process times. Furthermore, a vacuum laminator can no longer be employed from a module size of 2 m², since the path for the air bubbles to escape at the edge is too long, so that they can no longer escape during the conventional process time and are “frozen” in the adhesive. This results in losses due to reflection. The thermoplastic polyurethanes described in JP-A 09-312410 indeed soften during heating in a vacuum vessel, but they are not sufficiently liquid for the intermediate spaces between the solar cells to be filled up. Unusable solar modules are obtained as a result.

The Applications WO 99/52153 and WO 99/52154 claim the use of composite films or composite bodies of a polycarbonate layer and a fluorine polymer layer for encapsulating solar modules. The EVA hot-melt adhesive, which can be processed only slowly, is used for the gluing.

The Application DE-A 3 013 037 describes a symmetric construction of a solar module with a PC sheet on the front and reverse side, the embedding layer (adhesive layer) for the solar cells being characterized by a maximum E modulus of 1,000 MPa, which is much too hard and tears the fragile solar cells during thermal expansion.

EVA as a hot-melt adhesive must be melted at about 150° C.; EVA is then liquid, like water. If a module construction is now very heavy, in this state the EVA is pressed out to the side during the lamination and the effective thickness of the adhesive layer decreases accordingly. The crosslinking process starts at about 150° C. and requires between 15 and 30 minutes. Because of this long process time, EVA can be processed only discontinuously in a vacuum laminator. The processing window (time-dependent course of the pressure and temperature) is very narrow for EVA. Furthermore, EVA shows yellowing under UV irradiation, which is taken into account e.g. by doping with cerium as a UV absorber in the glass pane above it [F. J. Pern, S. H. Glick, Sol. Energy Materials & Solar Cells 61 (2000), pages 153-188].

Plastics have a considerably higher thermal expansion coefficient (50 to 150·10⁻⁶ K⁻¹) than silicon (2·10⁻⁶ K⁻¹) or glass (4·10⁻⁶ K⁻¹). If solar cells are therefore, encapsulated with plastics and not with glass, the silicon solar cells must be uncoupled mechanically from the plastic by a suitable flexible adhesive layer. However, the adhesive layer also must not be too flexible in order to impart to the entire solar module composite a still sufficient mechanical distortion rigidity. EVA solves this problem of the different expansion coefficients of silicon and plastics and of the distortion rigidity only inadequately.

### SUMMARY OF THE INVENTION

The object of the invention was to provide photovoltaic modules which are distinguished by a fast and inexpensive process for their production and a low weight.

It has been possible to achieve this object with the photovoltaic modules according to the present invention.

The present invention provides photovoltaic modules with the following construction:

A) at least one outer covering layer on the front side, facing the energy source, of glass or an impact-resistant, UV-stable, weathering-stable, transparent plastic with a low permeability to water vapor,

B) at least one outer layer on the reverse side, facing away from the energy source, of glass or a weathering-stable plastic with a low permeability to water vapor, and

C) at least one adhesive layer of plastic between A) and B) in which at least one more solar cells connected electrically to one another are embedded,

wherein the adhesive layer of plastic in C) comprises an aliphatic, thermoplastic polyurethane with a hardness of 75 Shore A to 70 Shore D, preferably 92 Shore A to 70 Shore D and with a softening temperature T_{sof} of from 90° to 150° C. at an E′-modulus of 2 MPa (measured according to the DMS-method), which is a reaction product of an aliphatic diisocyanate, at least one Zerewitinoff-active polyol with on average at least 1.8 to not more than 3.0 Zerewitinoff-active hydrogen atoms and with a number-average molecular weight of 600 to 10,000 g/mol and at least one Zerewitinoff-active polyol with on average at least 1.8 to not more than 3.0 Zerewitinoff-active hydrogen atoms and with a number-average molecular weight of 60 to 500 g/mol as a chain lengthener, the molar ratio of the NCO groups of the aliphatic diisocyanate to the OH groups of the chain lengthener and the polyol being 0.85 to 1.2.

### BRIEF DESCRIPTION OF THE DRAWINGS

FIG. 1 shows a solar module according to the present invention with cover sheet and reverse side film.

FIG. 2 shows a solar module according to the present invention with cover film and reverse side sheet.

FIG. 3 shows a diagram of the production of the composite of sheet and adhesive film.

FIG. 4 shows a diagram of the production of a solar module in a roller laminator.

FIG. 5 shows a diagram of the production of a continuous module in a roller laminator.

FIG. 6 shows a diagram of the dividing of a continuous module into standard modules.

FIG. 7 shows a diagram of a foldable solar module with film hinge.

### DETAILED DESCRIPTION OF THE INVENTION

The present invention provides photovoltaic modules with the following construction:

A) at least one outer covering layer on the front side, facing the energy source, of glass or an impact-resistant, UV-stable, weathering-stable, transparent plastic with a low permeability to water vapor,

B) at least one outer layer on the reverse side, facing away from the energy source, of glass or a weathering-stable plastic with a low permeability to water vapor, and

C) at least one adhesive layer of plastic between A) and B) in which at least one or more solar cells connected electrically to one another are embedded,

wherein the adhesive layer of plastic in C) comprises an aliphatic, thermoplastic polyurethane with a hardness of 75 Shore A to 70 Shore D, preferably 92 Shore A to 70 Shore D and with a softening temperature T_{sof} of from 90° to 150° C. at an E′-modulus of 2 MPa (measured according to the DMS-method), which is a reaction product of an aliphatic diisocyanate, at least one Zerwitinoff-active polyol with on average at least 1.8 to not more than 3.0 zerewitinoff-active hydrogen atoms and with a number-average molecular weight of 600 to 10,000 g/mol and at least one zerewitinoff-active polyol with on average at least 1.8 to not more than 3.0 Zerewitinoff-active hydrogen atoms and with a number-average molecular weight of 60 to 500 g/mol as a chain lengthener, the molar ratio of the NCO groups of the aliphatic diisocyanate to the OH groups of the chain lengthener and the polyol being 0.85 to 1.2, preferably 0.9 to 1.1.

Dynamic-mechanical Analysis (DMS-method)

Rectangles (30 mm×10 mm×1 mm) were stamped out of injection-molded sheets. These test sheets were subjected periodically to very small deformations under a constant pre-load—optionally dependent on the storage modulus—and the force acting on the clamp was measured as a function of the temperature and stimulation frequency.

The pre-load additionally applied serves to keep the specimen still adequately tensioned at the point in time of negative deformation amplitudes.

The softening temperature T_{sof} was determined as the characteristic temperature of the heat resistance at E′=2 MPa.

The DMS measurements were carried out with the Seiko DMS model 210 from Seiko with 1 Hz in the temperature range from −150° C. to 200° C. with a heating rate of 2° C./min.

The covering layer A) preferably comprises a sheet or one or more films.

The layer B) preferably comprises a sheet or one or more films.

The covering layer A) is preferably a film or sheet present in strips, the strips being arranged over the so-called solar cell strings.

The solar cells embedded in the adhesive layer of plastic C) are preferably arranged in solar cell strings.

The solar cell strings are preferably soldered in series or connected in series to each other by means of conductive adhesives, in order to generate the highest possible electrical voltage with the solar cells.

When using conductive adhesives, these are preferably positioned directly on the inside of the plastic adhesive layer (102, 111) in the form of so-called adhesive beads (20) [“Kleben, Grundlagen-Technologie-Anwendungen, Handbuch Münchener Ausbildungsseminar”, Axel Springer Verlag, Berlin, Heildelberg 1997], in such a manner that they fall directly onto the corresponding contacts of the solar cells (24) during lamination and have an overlapping region (21) which allows the solar cells to be connected in series (cf. FIG. 8). As a result, soldering prior to lamination can be dispensed with and the electrical connection and encapsulation are carried out in one step.

A glass film with a thickness of less than 500 μm is preferably additionally present between the covering layer A) and the solar cells in the adhesive layer of plastic C).

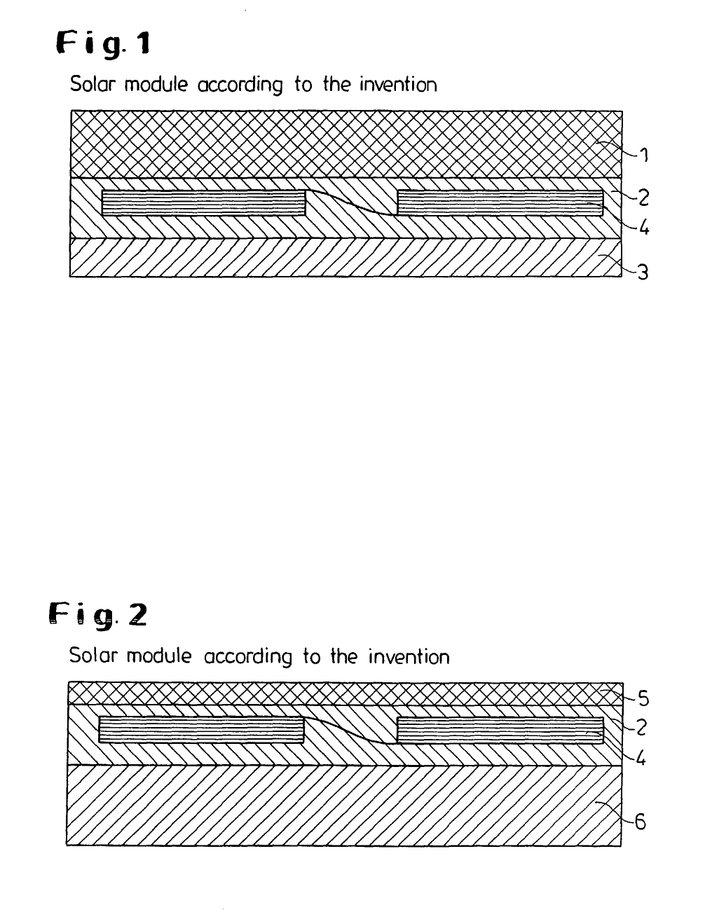

The solar module according to the present invention preferably comprises a transparent cover (1, 5) on the front side, an adhesive layer (2) enclosing the solar cells (4) and a reverse side (3, 6), which can be opaque or transparent (see FIG. 1 and FIG. 2). The cover should have the following properties: high transparency of 350 nm to 1,150 nm, high impact strength, stability to UV and weathering, low permeability to water vapor. The cover (1, 5) can be made of the following materials: glass, polycarbonate, polyester, polyvinyl chloride, fluorine-containing polymers, thermoplastic polyurethanes or any desired combinations of these materials. The cover (1, 5) can be constructed as a sheet, film or composite film. The reverse side (3, 6) should be stable to weathering and have a low permeability to water vapor and a high electrical resistance. In addition to the materials mentioned for the front side, the reverse side can also be made of polyamide, ABS or another plastic which is stable to weathering or a metal sheet or foil provided with an electrically insulating layer on the inside. The reverse side (3, 6) can be constructed as a sheet, film or composite film.

The adhesive layer (2) should have the following properties: high transparency of 350 nm to 1,150 nm and good adhesion to silicon, the aluminum reverse side contact of the solar cell, the tin-plated front side contacts, the antireflection layer of the solar cell and the material of the cover and of the reverse side. The adhesive layer can comprise one or more adhesive films, which can be laminated on to the cover and/or the reverse side.

The adhesive films (2) should be flexible, in order to compensate for the stresses which arise due to the different thermal expansion coefficients of the plastic and silicon. The adhesive films (2) should have an E modulus of less than 200 MPa and more than 1 MPa, preferably less than 140 MPa and more than 10 MPa, and a melting point below the melting temperature of the solder connections of the solar cells, which is typically 180° C. to 220° C. or below the Vicat softening point (heat stability) of the electrically conductive adhesives, which is typically higher than 200° C. The adhesive film should, furthermore, have a high electrical resistance, low absorption of water and high resistance to UV radiation and thermal oxidation, and be chemically inert and easy to process without crosslinking.

In a preferred embodiment of the invention, the cover and the reverse side comprise films or sheets of plastic. The total thickness of the cover and reverse side is at least 2 mm, preferably at least 3 mm. As a result, the solar cells are adequately protected from mechanical influences. The gluing comprises at least one adhesive film of a thermoplastic polyurethane with a total thickness of 300 to 1,000 μm.

Another preferred embodiment of the present invention is a solar module in which the cover and reverse side contain films with a thickness of less than 1 mm of the abovementioned materials, the composite being fixed to a suitable support of metal or plastic, which imparts the necessary rigidity to the entire system. The support of plastic is preferably a glass fiber-reinforced plastic.

Another preferred embodiment of the invention is a solar module in which the cover contains a film with a thickness of less than 1 mm of the abovementioned materials and the reverse side contains a multi-wall sheet of plastic to increase the rigidity with significant reduction in weight.

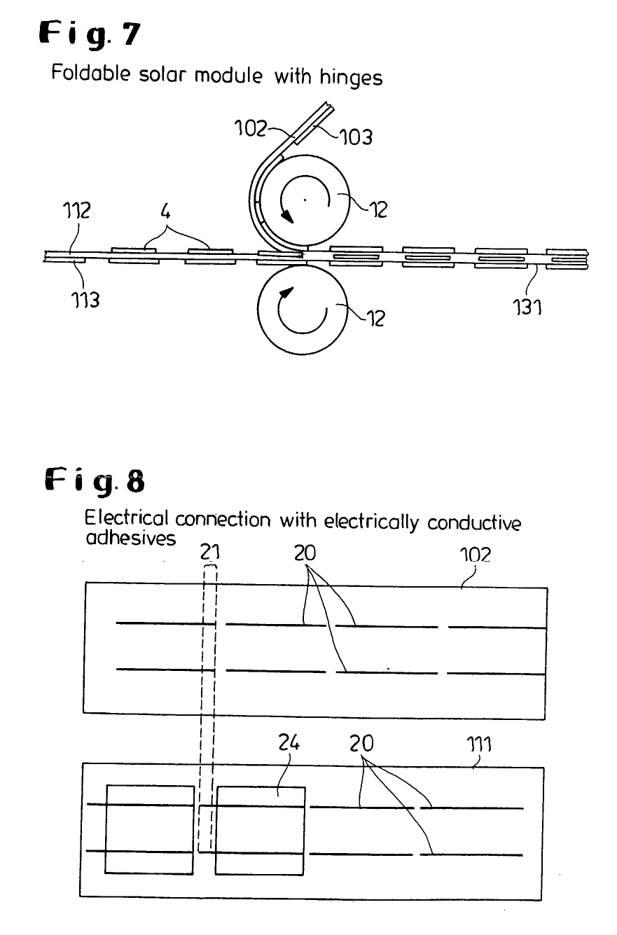

In another preferred embodiment of the invention, the cover (103) and/or the reverse side (113) contains films and sheets, in the form of strips, which have precisely the dimensions of a solar cell string. These are fixed on the adhesive film (102 or 111) at a distance of a few millimetres to centimeters, so that a region only with adhesive film without the cover or reverse side, which can serve e.g. as a film hinge (131), exists between the strings (see FIG. 7). Such a solar module can be either folded and/or rolled up, so that, for example, it is easier to transport. This solar module is more preferably constructed of lightweight plastics, so that it finds use in the camping sector, in the outdoor sector or in other mobile applications, such as mobile phones, laptops etc.

The invention also provides a process for the production of the photovoltaic modules according to the present invention, which is characterized in that the photovoltaic modules are produced in a vacuum plate laminator (vacuum hot press) or in a roller laminator.

The temperature during lamination is preferably at least 20° C. and at most 40° C. higher than the softening temperature T_{sof} of the thermoplastic polyurethane used.

A composite containing a cover plate or cover film and an adhesive film of plastic, a solar cell string and a composite comprising a film or sheet on the reverse side and an adhesive film of plastic are preferably fed over a roller laminator and thereby pressed and glued to give the solar module.

A roller laminator comprises at least two rolls running in opposite directions, which rotate with a defined speed and press a composite of various materials against one another with a defined pressure at a defined temperature.

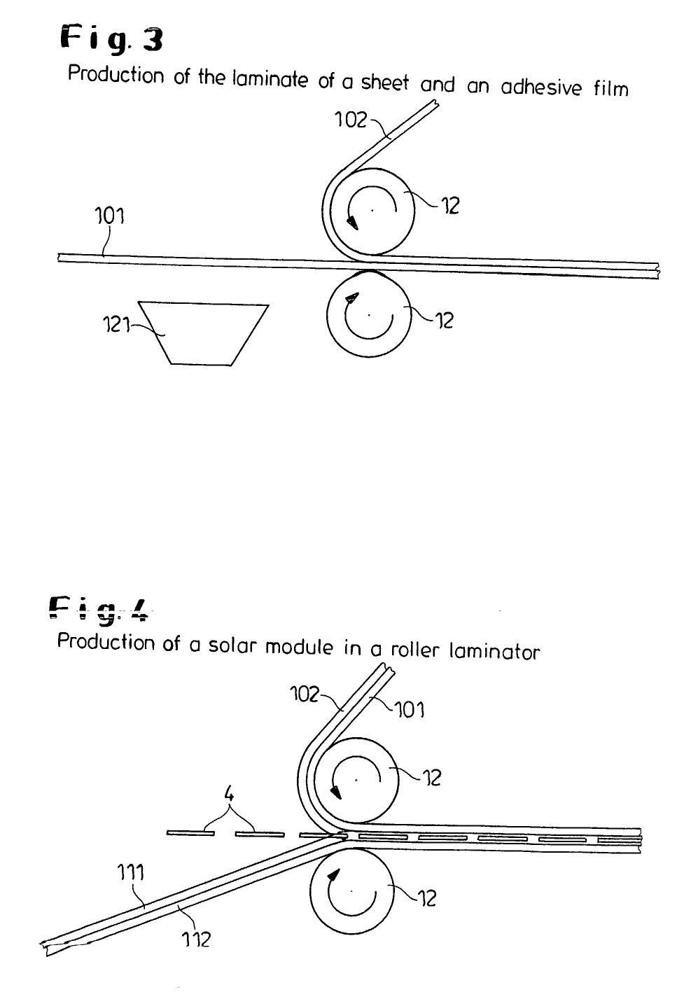

In a preferred embodiment of the process, laminates of a sheet or film (101) and the adhesive film (102) are produced in a roller laminator (12) in the first step (see FIG. 3). This roller laminator can be directly downstream of the extruder for extruding the films. Thereafter, the following composites/layers are introduced one above the other in a roller laminator (12) in the second step: composite of cover (101) with adhesive film (102); solar strings (4); composite of reverse side (112) with adhesive film (111) (see FIG. 4). The adhesive films here are in each case laminated or coextruded on to the inside of the cover or of the reverse side. At a thickness of more than 1 mm in the case of the cover or the reverse side, this can no longer be heated by a roll in a roller laminator because of the low thermal conduction. In such a case radiant heating or another type of preheating is then necessary in order to preheat the sheet to a corresponding temperature. The temperature in the roller laminator should be high enough for the adhesive films to fill up all the intermediate spaces between the solar cells/solar cell strings and to be welded to one another without the solar cells thereby being broken.

In this manner, it is possible to produce solar modules of any desired size without air bubbles occurring in the finished module and adversely influencing the quality of the module as a result.

The feed velocity with which the films are processed in a roller laminator is preferably 0.1 m/min to 3 m/min, more preferably 0.2 m/min to 1 m/min.

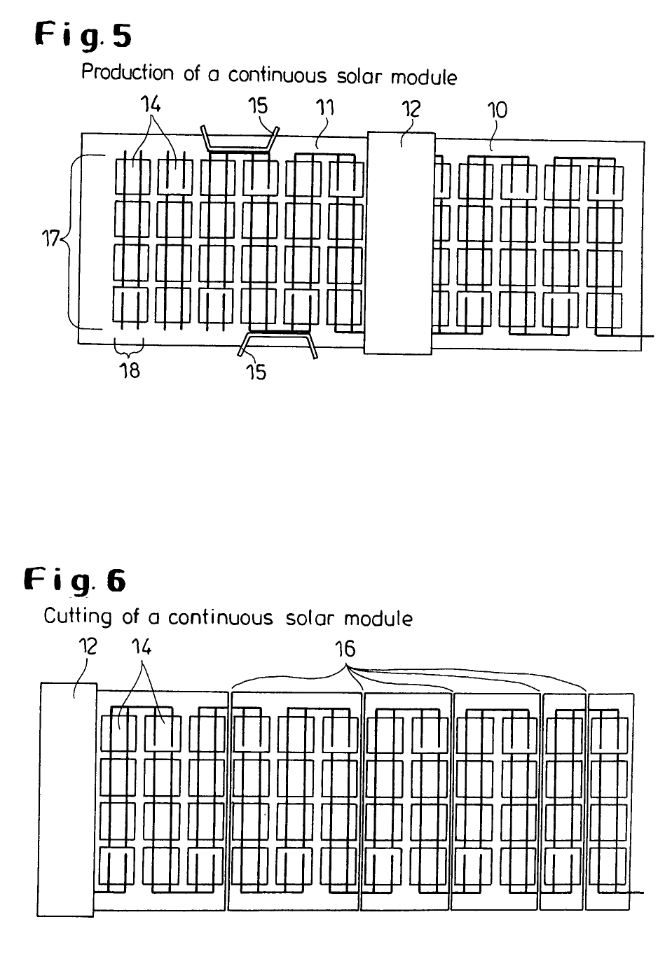

In another preferred embodiment of the process, the solar module is produced as a continuous solar module, i.e. the cover (10), reverse side (11) and solar cell strings (14) are glued to one another by the roller laminator (12) in a continuous process (see FIG. 5). In this, the soldered or adhesively connected solar cell strings are positioned on the reverse side films at right angles to the laminating direction. Before the strings then arrive at the roll, they are soldered on the right and left with the preceding and subsequent string, respectively, or connected to each other with conductive adhesives in a manner familiar to the expert (15). A module of any desired length can thus be produced. After the module has been laminated, it can be divided into various lengths, the width always corresponding to the string length (17) and the length corresponding to a multiple of the string width (18). The modules are cut along the lines (16) with a cutting device (see FIG. 6).

Aliphatic diisocyanates (A) which can be used are aliphatic and cycloaliphatic diisocyanates or mixtures of these diisocyanates (cf. HOUBEN-WEYL “Methoden der Organischen Chemie [Methods of Organic Chemistry]”, volume E20 “Makromolekulare Stoffe [Macromolecular Substances]”, Georg Thieme Verlag, Stuttgart, New York 1987, p. 1587-1593 or Justus Liebigs Annalen der Chemie, 562, pages 75 to 136).

There may be mentioned specifically, by way of example: aliphatic diisocyanates, such as ethylene diisocyanate, 1,4-tetramethylene-diisocyanate, 1,6-hexamethylene-diisocyanate and 1,12-dodecane-diisocyanate; cycloaliphatic diisocyanates, such as isophorone-diisocyanate, 1,4-cyclohexane-diisocyanate, 1-methyl-2,4-cyclohexane-diisocyanate and 1-methyl-2,6-cyclohexane-diisocyanate and the corresponding isomer mixtures, 4,4′-dicyclohexylmethane-diisocyanate, 2,4′-dicyclohexylmethane-diisocyanate and 2,2′-dicyclohexylmethane-diisocyanate and the corresponding isomer mixtures. 1,6-Hexamethylene-diisocyanate, 1,4-cyclohexane-diisocyanate, isophorone-diisocyanate and dicyclohexylmethane-diisocyanate and isomer mixtures thereof are preferably used. The diisocyanates mentioned can be used individually or in the form of mixtures with one another. They can also be used together with up to 15 mol % (calculated for the total diisocyanate) of a polyisocyanate, but at most an amount of polyisocyanate should be added such that a product which can still be processed as a thermoplastic is formed.

Zerewitinoff-active polyols (B) which are employed according to the present invention are those with on average at least 1.8 to not more than 3.0 Zerewitinoff-active hydrogen atoms and a number-average molecular weight \overline{M}ₙ of 600 to 10,000, preferably 600 to 6,000.

In addition to compounds containing amino groups, thiol groups or carboxyl groups, these include, in particular, compounds containing two to three, preferably two, hydroxyl groups, specifically those with number-average molecular weights \overline{M}ₙ of 600 to 10,000, more preferably those with a number-average molecular weight \overline{M}ₙ of 600 to 6,000; e.g. polyesters, polyethers, polycarbonates and polyester-amides containing hydroxyl groups.

Suitable polyether diols can be prepared by reacting one or more alkylene oxides having 2 to 4 carbon atoms in the alkylene radical with a starter molecule which contains two bonded active hydrogen atoms. Alkylene oxides, which may be mentioned are e.g.: ethylene oxide, 1,2-propylene oxide, epichlorohydrin and 1,2-butylene oxide and 2,3-butylene oxide. Ethylene oxide, propylene oxide and mixtures of 1,2-propylene oxide and ethylene oxide are preferably used. The alkylene oxides can be used individually, in alternation in succession or as mixtures. Examples of possible starter molecules are: water, amino-alcohols, such as N-alkyl-diethanolamines, for example N-methyl-diethanolamine, and diols, such as ethylene glycol, 1,3-propylene glycol, 1,4-butanediol and 1,6-hexanediol. Mixtures of starter molecules can also optionally be employed. Suitable polyether-ols are, furthermore, the polymerization products of tetrahydrofuran which contain hydroxyl groups. It is also possible to employ trifunctional polyethers in amounts of 0 to 30 wt. %, based on the bifunctional polyethers, but at most in an amount such that a product which can still be processed as a thermoplastic is formed. The substantially linear polyether diols preferably have number-average molecular weights \overline{M}ₙ of 600 to 10,000, more preferably 600 to 6,000. They can be used both individually and in the form of mixtures with one another.

Suitable polyester diols can be prepared, for example, from dicarboxylic acids having 2 to 12 carbon atoms, preferably 4 to 6 carbon atoms, and polyhydric alcohols. Examples of possible dicarboxylic acids are: aliphatic dicarboxylic acids, such as succinic acid, glutaric acid, adipic acid, suberic acid, azelaic acid and sebacic acid, or aromatic dicarboxylic acids, such as phthalic acid, isophthalic acid and terephthalic acid. The dicarboxylic acids can be used individually or as mixtures, e.g. in the form of a succinic, glutaric and adipic acid mixture. To prepare the polyester diols, it may optionally be advantageous to use, instead of the dicarboxylic acids, the corresponding dicarboxylic acid derivatives, such as carboxylic acid diesters having 1 to 4 carbon atoms in the alcohol radical, carboxylic acid anhydrides or carboxylic acid chlorides. Examples of polyhydric alcohols are glycols having 2 to 10, preferably 2 to 6 carbon atoms, e.g. ethylene glycol, diethylene glycol, 1,4-butanediol, 1,5-pentanediol, 1,6-hexanediol, 1,10-decanediol, 2,2-dimethyl-1,3-propanediol, 1,3-propanediol or dipropylene glycol. The polyhydric alcohols can be used by themselves or as a mixture with one another, depending on the desired properties. Esters of carbonic acid with the diols mentioned, in particular those having 4 to 6 carbon atoms, such as 1,4-butanediol or 1,6-hexanediol, condensation products of ω-hydroxycarboxylic acids, such as ω-hydroxycaproic acid, or polymerization products of lactones, e.g. optionally substituted ω-caprolactones, are furthermore suitable. Ethanediol polyadipates, 1,4-butanediol polyadipates, ethanediol-1,4-butanediol polyadipates, 1,6-hexanediol-neopentylglycol polyadipates, 1,6-hexanediol-1,4-butanediol polyadipates and polycaprolactones are preferably used as the polyester diols. The polyester diols have average molecular weights \overline{M}ₙ of 600 to 10,000, preferably 600 to 6,000, and can be used individually or in the form of mixtures with one another.

Zerewitinoff-active polyols (C) are so-called chain lengthening agents and have on average 1.8 to 3.0 Zerewitinoff-active hydrogen atoms and have a number-average molecular weight of 60 to 500. In addition to compounds containing amino groups, thiol groups or carboxyl groups, these are understood as meaning those with two to three, preferably two, hydroxyl groups.

Chain lengthening agents which are preferably employed are aliphatic diols having 2 to 14 carbon atoms, such as e.g. ethanediol, 1,2-propanediol, 1,3-propanediol, 1,4-butanediol, 2,3-butanediol, 1,5-pentanediol, 1,6-hexanediol, diethylene glycol and dipropylene glycol. However, diesters of terephthalic acid with glycols having 2 to 4 carbon atoms, e.g. terephthalic acid bis-ethylene glycol or terephthalic acid bis-1,4-butanediol, hydroxyalkylene ethers of hydroquinone, e.g. 1,4-di(β-hydroxyethyl)-hydroquinone, ethoxylated bisphenols, e.g. 1,4-di(β-hydroxyethyl)-bisphenol A, (cyclo)aliphatic diamines, such as isophoronediamine, ethylenediamine, 1,2-propylenediamine, 1,3-propylenediamine, N-methyl-propylene-1,3-diamine or N,N′-dimethylethylenediamine, and aromatic diamines, such as 2,4-toluylenediamine, 2,6-toluylenediamine, 3,5-diethyl-2,4-toluylene-diamine or 3,5-diethyl-2,6-toluylenediamine, or primary mono-, di-, tri- or tetraalkyl-substituted 4,4′-diaminodiphenylmethanes, are also suitable. Ethanediol, 1,4-butanediol, 1,6-hexanediol, 1,4-di(β-hydroxyethyl)-hydroquinone or 1,4-di(β-hydroxyethyl)-bisphenol A are more preferably used as chain lengtheners. It is also possible to employ mixtures of the abovementioned chain lengtheners. In addition, smaller amounts of triols can also be added.

Compounds which are monofunctional towards isocyanates can be employed as so-called chain terminators in amounts of up to 2 wt. %, based on the aliphatic thermoplastic polyurethane. Suitable compounds are e.g. monoamines, such as butyl- and dibutylamine, octylamine, stearylamine, N-methylstearylamine, pyrrolidine, piperidine or cyclohexylamine, and monoalcohols, such as butanol, 2-ethylhexanol, octanol, dodecanol, stearyl alcohol, the various amyl alcohols, cyclohexanol and ethylene glycol monomethyl ether.

The relative amounts of compounds (C) and (B) are preferably chosen such that the ratio of the sum of isocyanate groups in (A) to the sum of Zerewitinoff-active hydrogen atoms in (C) and (B) is 0.85:1 to 1.2:1, preferably 0.95:1 to 1.1:1.

The thermoplastic polyurethane elastomers (TPU) employed according to the present invention can comprise as auxiliary substances and additives (D) up to a maximum of 20 wt. %, based on the total amount of TPU, of conventional auxiliary substances and additives. Typical auxiliary substances and additives are catalysts, pigments, dyestuffs, flameproofing agents, stabilizers against aging and weathering influences, plasticizers, lubricants and mold release agents, fungistatically and bacteriostatically active substance and fillers, and mixtures thereof.

Suitable catalysts are the conventional tertiary amines known according to the prior art, such as e.g. triethylamine, dimethylcyclohexylamine, N-methylmorpholine, N,N′-dimethylpiperazine, 2-(dimethylamino-ethoxy)ethanol, diazabicyclo[2,2,2]octane and the like, and, in particular, organometallic compounds, such as titanic acid esters, iron compounds or tin compounds, such as tin diacetate, tin dioctoate, tin dilaurate or the tin-dialkyl salts of aliphatic carboxylic acids, such as dibutyltin diacetate or dibutyltin dilaurate or the like. Preferred catalysts are organometallic compounds, in particular titanic acid esters and compounds of iron and tin. The total amount of catalysts in the TPU is as a rule about 0 to 5 wt. %, preferably 0 to 2 wt. %, based on the total amount of TPU.

Examples of further additives are lubricants, such as fatty acid esters, metal soaps thereof, fatty acid amides, fatty acid ester-amides and silicone compounds, antiblocking agents, inhibitors, stabilizers against hydrolysis, light, heat and discoloration, flameproofing agents, dyestuffs, pigments, inorganic and/or organic fillers and reinforcing agents. Reinforcing agents are, in particular, fibrous reinforcing substances, such as e.g. inorganic fibers, which are prepared according to the prior art and can also be charged with a size. More detailed information on the auxiliary substances and additives mentioned can be found in the technical literature, for example the monograph by J. H. Saunders and K. C. Frisch “High Polymers”, volume XVI, Polyurethane [Polyurethanes], part 1 and 2, Verlag lnterscience Publishers 1962 and 1964, the Taschenbuch für Kunststoff-Additive [Handbook of Plastics Additives] by R. Gächter and H. Müller (Hanser Verlag Munich 1990) or DE-A 29 01 774.

Further additives which can be incorporated into the TPU are thermoplastics, for example polycarbonates and acrylonitrile/butadiene/styrene terpolymers, in particular, ABS. Other elastomers, such as rubber, ethylene/vinyl acetate copolymers, styrene/butadiene copolymers and other TPU, can also be used.

Commercially available plasticizers, such as phosphates, phthalates, adipates, sebacates and alkylsulfonic acid esters, are furthermore, suitable for incorporation.

The preparation of the TPU can be carried out discontinuously or continuously. The TPU can be prepared continuously, for example, by the mixing head/belt process or the so-called extruder process. In the extruder process, e.g. in a multi-shaft extruder, metering of components (A), (B) and (C) can be carried out simultaneously, i.e. in the one-shot process, or successively, i.e. by a prepolymer process. It is possible here for the prepolymers either to be initially introduced batchwise or to be prepared continuously in a part of the extruder or in a separate preceding prepolymer unit.

The invention is to be illustrated in more detail with the aid of the following example.

### EXAMPLE 1

A film of Texine® DP7-3007 (commercial product from Bayer Corp., hardness: 58 Shore D) was extruded on to a Makrofol® film as follows: A vertical die arrangement was attached to an extruder with a roll unit from Reifenhäuser (with a chill roll). The casting roll of the unit was preceded by a backing roll with a rubber-covered surface. The die was positioned between the casting roll and backing roll. To achieve a wind-up speed which is very slow for this “chill roll” unit, the film composite was taken off by only one winder. To improve the adhesion of the Texin® melt to the Makrofol® film DE 1-1 employed (with a thickness of 375 μm (commercial product of Bayer AG)), the Makrofol® film was preheated with IR lamps before feeding in the melt. The Texin® was predried in a dry air dryer for 6 h at 60° C.

The following processing parameters were established:

| | |
|---|---|
| Die temperature | 180° C. |
| Material temperature of the Texin ® | 186° C. |
| Pressure before the die | 75 bar |
| Speed of rotation of the extruder | 80 rpm |
| Temperature at the casting roll | 20° C. |
| Temperature at the chill roll | 10° C. |
| Wind-up speed | 3 m/min |

The composite film produced in this way was then laminated as the cover, with the Texin® side on the bottom, and as the reverse side, with the Texin® side on the top, on to solar cell strings arranged in between in a roller laminator by means of hot rollers at 160° C. For optimum gluing, the composite films were preheated with an IR lamp. The feed velocity of the roller laminator was 0.3 m/min. The modules 15×15 cm² in size could be produced in 30 seconds.

Several bubble-free solar modules (modules 4 and 5) into which the solar cells were embedded without cracks and breaks were produced.

The efficiency of the solar cells remained unchanged by the production process.

The solar modules were subjected to weathering in two different tests. The efficiencies before and after the weathering are shown in the table.

### EXAMPLE 2

A film was extruded using Desmopan® 88 382 (commercial product from Bayer AG, hardness:80 Shore A) as follows:

A horizontal die arrangement was attached to an extruder with a roll unit from Somatec (with a chill roll). The chill roll was positioned about 5 cm below the die.

To achieve a wind up speed which is very slow for this “chill roll” unit, the film was taken off by only one winder. The Desmopan® was predried in a dry air dryer for 6 h at 75° C.

The following processing parameters were established:

Die temperature 170° C.

Material temperature of the Texin® 177° C.

Pressure before the die 27 bar

Speed of rotation of the extruder 40 rpm

Temperature at the chill roll 10° C.

Wind up speed 1.7 m/min

The film produced in this way was then used as an adhesive layer in a solar module as described in FIG. 1. The top side of the module (15×15 cm²) was made of hardened white glass and the reverse side of a composite film (Tedlar-PET-Tedlar). The solar modules were produced at 150° C. in 10 minutes in a vacuum laminator.

Several bubble-free solar modules (modules 4 and 5) into which the solar cells were embedded without cracks and breaks were produced.

The efficiency of the solar cells remained unchanged by the production process.

The solar modules were subjected to weathering in two different tests. The efficiencies before and after the weathering are shown in the table.

Comparison

Comparison modules were produced. Instead of the Texin® DP7-3007, EVA (ethylene/vinyl acetate) was employed. The production time for the modules 15×15 cm² in size was 20 minutes and production took place in a vacuum laminator. The comparison modules were also subjected to weathering (see table).

TABLE 1

| | | Efficiency | Efficiency |
|---|---|---|---|
| | | after | after |
| | | weathering | weathering |
| | | in the | in the |
| | Efficiency | thermal | damp heat |
| | before | cycling | test** |
| Modules | weathering | test* (IEC 61215) | (IEC 61215) |
| 1 | 13.8% | 13.7% | — |
| 2 | 13.3% | 13.5% | — |
| 3 | 13.5% | — | 13.5% |
| 4 | 15.2% | 15.1% | — |
| 5 | 14.7% | — | 14.8% |
| Comparison 1 | 13.2% | 13.3% | — |
| Comparison 2 | 13.9% | — | 14.1% |

*50 cycles from −40° C. to +85° C. at a cycle length of approx. 6 h
**500 h at 80° C. and 85% rel. atmospheric humidity

The measurement error in the determination of the efficiency is ±0.3% absolute.

The efficiency is measured in accordance with IEC 61215.

The solar modules according to the invention have the same efficiencies as the comparison modules (prior art) and have the same mechanical stability and stability to weathering. The efficiencies are retained even after weathering.

However, it was possible to produce the solar modules according to the invention considerably faster (factor of 40 in the roller laminator and factor of 2 in the vacuum laminator) than the comparison modules.

Although the invention has been described in detail in the foregoing for the purpose of illustration, it is to be understood that such detail is solely for that purpose and that variations can be made therein by those skilled in the art without departing from the spirit and scope of the invention except as limited by the claims.

What is claimed is:

1. Photovoltaic modules comprising:
A) at least one outer covering layer on the front side, facing the energy source, of glass or an impact-resistant, UV-stable, weathering-stable, transparent plastic with a low permeability to water vapor,
B) at least one outer layer on the reverse side, facing away from the energy source, of glass or a weathering-stable plastic with a low permeability to water vapor, and
C) at least one adhesive layer of plastic between A) and B) in which at least one or more solar cells connected electrically to one another are embedded,
wherein the adhesive layer of plastic C) comprises an aliphatic, thermoplastic polyurethane with a hardness of 75 Shore A to 70 Shore D, and with a softening temperature T_{sof} of 90° C. to 150° C. at an E′-modulus of 2 MPa (measured according to the DMS-method), which is a reaction product of an aliphatic diisocyanate, at least one Zerewitinoff-active polyol with on average at least 1.8 to not more than 3.0 Zerewitinoff-active hydrogen atoms and with a number-average molecular weight of 600 to 10,000 g/mol and at least one Zerewitinoff-active polyol with an average at least 1.8 to not more than 3.0 Zerewitinoff-active hydrogen atoms and with a number-average molecular weight of 60 to 500 g/mol as a chain lengthener, the molar ratio of the NCO groups of the aliphatic diisocyanate to the OH groups of the chain lengthener and the polyol being 0.85 to 1.2.

2. Photovoltaic modules according to claim 1 wherein the molar ratio of the NCO groups of the aliphatic diisocyanate to the OH groups of the chain lengthener and the polyol is 0.9 to 1.1.

3. Photovoltaic module according to claim 1, wherein the cover layer A) comprises a sheet or one or more films.

4. Photovoltaic module according to claim 1, wherein the layer B) comprises a sheet or one or more films.

5. Photovoltaic module according to claim 1, wherein the cover layer A) is a film or sheet present in strips, the strips being arranged over the so-called solar cell strings.

6. Photovoltaic module according to claim 1, wherein the solar cells embedded in the adhesive layer of plastic C) are arranged in solar cell strings.

7. Photovoltaic module according to claim 6, wherein the solar cell strings are soldered or connected by means of conductive adhesives one after the other in series.

8. Photovoltaic module according to claim 7, wherein the electrical connection between the solar cells consists of conductive adhesives which is applied directly to the inside of the adhesive layer of plastic C), preferably in the form of beads, so that they fall directly onto the corresponding contacts of the solar cells during lamination.

9. Photovoltaic module according to claim 1, wherein a glass film with a thickness of less than 500 μm is additionally present in the adhesive layer of plastic C) between the cover layer A) and the solar cells.

10. Process for the production of the photovoltaic modules comprising:
A) at least one outer covering layer on the front side, facing the energy source, of glass or an impact-resistant, UV-stable, weathering-stable, transparent plastic with a low permeability to water vapor,
B) at least one outer layer on the reverse side, facing away from the energy source, of glass or a weathering-stable plastic with a low permeability to water vapor, and
C) at least one adhesive layer of plastic between A) and B) in which at least one or more solar cells connected electrically to one another are embedded,
wherein the adhesive layer of plastic C) comprises an aliphatic, thermoplastic polyurethane with a hardness of 75 Shore A to 70 Shore D, and with a softening temperature T_{sof} of 90° C. to 150° C. at an E′-modulus of 2 MPa (measured according to the DMS-method), which is a reaction product of an aliphatic diisocyanate, at least one Zerewitinoff-active polyol with on average at least 1.8 to not more than 3.0 Zerewitinoff-active hydrogen atoms and with a number-average molecular weight of 600 to 10,000 g/mol and at least one Zerewitinoff-active polyol with an average at least 1.8 to not more than 3.0 Zerewitinoff-active hydrogen atoms and with a number-average molecular weight of 60 to 500 g/mol as a chain lengthener, the molar ratio of the NCO groups of the aliphatic diisocyanate to the OH groups of the chain lengthener and the polyol being 0.85 to 1.2,
wherein said process comprises the step of producing the photovoltaic module in a vacuum sheet laminator or in a roller laminator.

11. A process according to claim 10, wherein a composite comprising a cover sheet or cover film and an adhesive film of plastic, a solar cell string and a composite comprising a film or sheet on the reverse side and an adhesive film of plastic are fed over a roller laminator and thereby pressed and glued to give the solar module.
